(19) United States
(12) Patent Application Publication
(10) Pub. No.: US 2025/0191898 A1
(43) Pub. Date: Jun. 12, 2025

(54) PLASMA PROCESSING METHOD AND PLASMA PROCESSING SYSTEM

(71) Applicant: Tokyo Electron Limited, Tokyo (JP)

(72) Inventors: Akira TANABE, Gyeonggi-do (KR); Kazuki NARISHIGE, Paya Lebar Quarter (SG); Katsunori HIRAI, Miyagi (JP); Yusuke TAMAKAWA, Miyagi (JP)

(73) Assignee: Tokyo Electron Limited, Tokyo (JP)

(21) Appl. No.: 19/055,821

(22) Filed: Feb. 18, 2025

Related U.S. Application Data
(63) Continuation of application No. PCT/JP2023/029596, filed on Aug. 16, 2023.

(30) Foreign Application Priority Data
Aug. 25, 2022 (JP) 2022-134310

(51) Int. Cl. H01J 37/32; C23C 16/44

(52) U.S. Cl. CPC H01J 37/32926; C23C 16/4405; H01J 2237/221; H01J 2237/24578; H01J 2237/332; H01J 2237/334

(57) ABSTRACT

A plasma processing method includes (A) performing plasma processing on a substrate introduced into a processing chamber, (B) calculating a thickness of a reaction product deposited on the substrate by (A), (C) setting a time for dry cleaning to remove a reaction product deposited inside the processing chamber by (A) based on the thickness of the reaction product deposited on the substrate calculated in (B), and (D) performing the dry cleaning for the time set in (C) in a state where the substrate is unloaded from the processing chamber.

### CROSS-REFERENCE TO RELATED APPLICATIONS

This application is a bypass continuation application of international application No. PCT/JP2023/029596 having an international filing date of Aug. 16, 2023 and designating the United States, the international application being based upon and claiming the benefit of priority from Japanese Patent Application No. 2022-134310, filed on Aug. 25, 2022, the entire contents of each are incorporated herein by reference.

### TECHNICAL FIELD

The present disclosure relates to a plasma processing system and a plasma processing method.

### BACKGROUND

PTL 1 discloses a semiconductor producing device that includes a cleaning unit that cleans a film deposited on an inner wall of a reaction chamber in which a film formation process is performed. In this semiconductor producing device, a film formation sequence controller and a deposition film thickness calculation unit calculate a film thickness deposited on a semiconductor substrate, and an etching time determination unit determines an etching time for cleaning the reaction chamber.

### CITATION LIST

### Patent Documents

PTL 1: JPH05-97579A

### SUMMARY

According to the technique in the present disclosure, a time for dry cleaning performed between wafer processes in a plasma processing apparatus is appropriately set.

An aspect of the present disclosure is a plasma processing method, which includes: (A) performing plasma processing on a substrate introduced into a processing chamber, (B) calculating a thickness of a reaction product deposited on the substrate by (A), (C) setting a time for dry cleaning to remove a reaction product deposited inside the processing chamber by (A) based on the thickness of the reaction product deposited on the substrate calculated in (B), and (D) performing the dry cleaning for the time set in (C) in a state where the substrate is unloaded from the processing chamber.

According to the present disclosure, a time for dry cleaning performed between wafer processes in a plasma processing apparatus can be appropriately set.

### BRIEF DESCRIPTION OF DRAWINGS

FIG. 1 is a diagram schematically illustrating a configuration of a plasma processing system according to the present embodiment.

FIG. 2 is a vertical sectional view illustrating a schematic configuration of a plasma processing apparatus.

FIG. 3 is a cross-sectional view illustrating a schematic configuration of an inspection apparatus.

FIG. 4 is a vertical sectional view illustrating a schematic configuration of the inspection apparatus.

FIG. 5 is a functional block diagram of an inspection control device and a main control device that configure a controller.

FIG. 6 is a diagram illustrating a deposition position of reaction products in a chamber.

FIG. 7 is a flow chart illustrating main steps of a plasma processing method according to the present embodiment.

FIG. 8 is a diagram illustrating reaction products deposited on a substrate.

FIG. 9 is a diagram illustrating reaction products deposited in the vicinity of an outer end of a rear surface of the substrate.

### DETAILED DESCRIPTION

In processes of manufacturing a semiconductor device, a plasma etching processing is performed using a mask layer on which a pattern is formed as a mask on an etching target layer formed by stacking on a surface of a semiconductor substrate (hereinafter, simply referred to as a “substrate”). In this plasma etching process, a temperature of the substrate is set to an extremely low temperature so that an etching rate and mask selectivity are improved.

However, in such a plasma etching process, organic deposits (hereinafter, referred to as “deposits”), which are reaction products during etching, adhere to an inner wall surface of a processing chamber or a chamber internal member. Therefore, between etching processing of the substrate, dry cleaning (wafer less dry cleaning: WLDC) is performed to remove deposits, as disclosed in PTL 1.

In the dry etching processing at the extremely low temperature described above, a film thickness of a polymer (backside polymer: BSP) adhering to a vicinity of an outer end of a rear surface of the substrate as a processing target or a film thickness of a polymer adhering to the chamber internal member (for example, a shoulder of an electrostatic chuck or a ring assembly) disposed near an outer end of the substrate becomes particularly large. Therefore, in the dry etching process, a time required for the WLDC becomes long, which lowers throughput. On the other hand, when the time for the WLDC is shortened, arcing may occur due to deposits remaining in the processing chamber.

In particular, as described in PTL 1, when a cleaning time for the reaction chamber is determined by simply calculating the film thickness of the deposit deposited on the semiconductor substrate, the polymer deposited on the chamber internal member disposed near the outer end of the substrate described above in the reaction chamber cannot be appropriately removed, and arcing may occur.

As such, improved throughput and prevention of arcing by optimizing a time for the WLDC performed between etching processing of the substrate is desired.

According to the technique in the present disclosure, a time for dry cleaning performed between wafer processes in a plasma processing apparatus is appropriately set. Hereinafter, a plasma processing method according to the present embodiment that includes a dry cleaning process, and a plasma processing system that executes the dry cleaning process will be described with reference to the drawings. Like reference numerals will be given to like parts having substantially the same functions throughout the specification and the drawings, and redundant description thereof will be omitted.

### <Plasma Processing System>

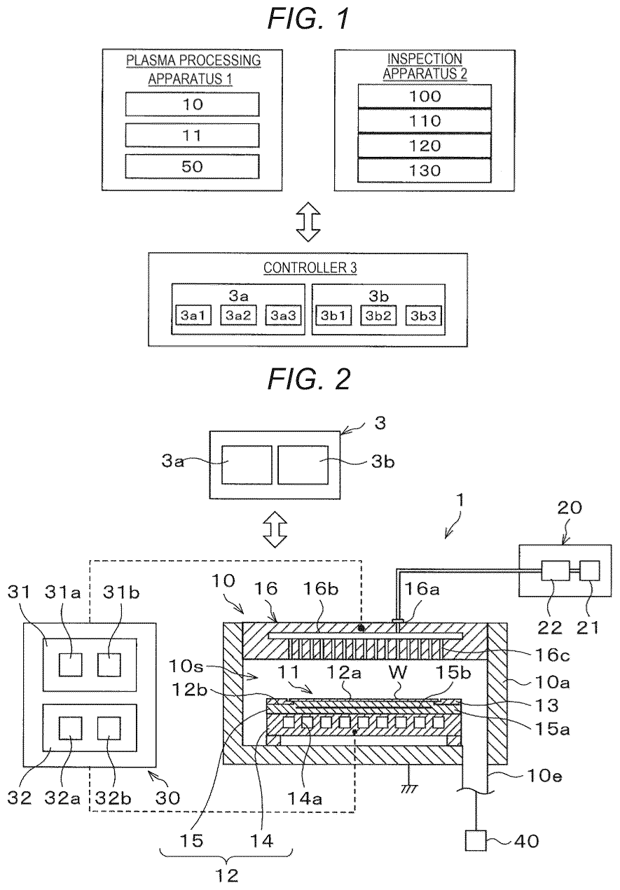

FIG. 1 is a diagram illustrating an example of a configuration of a plasma processing system. In one embodiment, the plasma processing system includes a plasma processing apparatus 1, an inspection apparatus 2, and a controller 3. The plasma processing system is an example of a substrate processing system, and the plasma processing apparatus 1 is an example of the substrate processing apparatus. An example of the inspection apparatus 2 is an imaging apparatus provided with a camera.

The plasma processing apparatus 1 includes a plasma processing chamber 10, a substrate support 11, and a plasma generator 50. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting the substrate.

The plasma generator 50 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The inspection apparatus 2 includes a casing 100, a stage 110, a surface imaging device 120, and an end imaging device 130. The inspection apparatus 2 loads the substrate after plasma processing in the plasma processing apparatus 1, and images the substrate on the stage 110 by the surface imaging device 120 and the end imaging device 130. Accordingly, a film thickness of deposits deposited on a surface of the substrate after the plasma processing and a film thickness of a polymer (hereinafter referred to as “BSP”) adhering to the vicinity of the outer end of the rear surface of the substrate are measured.

A configuration of the inspection apparatus 2 is not limited to the imaging apparatus provided with the imaging device, and may be any apparatus as long as the apparatus can measure the film thickness of the deposit, particularly the BSP, deposited on the substrate after plasma processing.

The controller 3 includes a main control device 3a and an inspection control device 3b. In one embodiment, the inspection control device 3b executes control for processes related to the inspection apparatus 2 among various processes described in the present disclosure, and the main control device 3a executes control for the other processes. In one embodiment, the main control device 3a and the inspection control device 3b process computer-executable instructions for causing the plasma processing system to execute various processes described in the present disclosure. The main control device 3a and the inspection control device 3b may be configured to control the plasma processing system to execute various processes to be described herein. In one embodiment, the main control device 3a and the inspection control device 3b may be partially or entirely in the plasma processing system. The main control device 3a may include a processor 3al, a storage 3a2, and a communication interface 3a3. Similarly, the inspection control device 3b may include a processor 3bl, a storage 3b2, and a communication interface 3b3. The main control device 3a and the inspection control device 3b are implemented by computers (not illustrated). The processors 3al and 3b1 may be configured to read programs from the storages 3a2 and 3b2, respectively, and perform various control operations by executing the read program. The program may be stored in advance in the storages 3a2 and 3b2, or may be acquired via a medium when necessary. The acquired program is stored in the storages 3a2 and 3b2, and read and executed from the storages 3a2 and 3b2 by the processors 3al and 3b1. The medium may be any of various recording media readable by the computer, or may be a communication line connected to each of the communication interfaces 3a3 and 3b3. The processors 3al and 3b1 may be a central processing unit (CPU). The storages 3a2 and 3b2 may include a random access memory (RAM), a read only memory (ROM), a hard disk drive (HDD), a solid state drive (SSD), or a combination thereof. The communication interfaces 3a3 and 3b3 may communicate with the plasma processing apparatus 1 and the inspection apparatus 2, respectively via a communication line such as a local area network (LAN). Further, the storage medium may be temporary or non-temporary medium.

The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

### <Plasma Processing Apparatus>

Next, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, the power source 30, and the exhaust system 40. The plasma processing apparatus 1 includes the substrate support 11 and a gas introduction unit. The substrate support 11 is disposed in the plasma processing chamber 10. The gas introduction unit is configured to introduce at least one processing gas into the plasma processing chamber 10. The gas introduction unit includes a shower head 16. The shower head 16 is disposed above the substrate support 11. In one embodiment, the shower head 16 forms at least a part of a ceiling of the plasma processing chamber 10. A plasma processing space 10s defined by the shower head 16, a sidewall 10a of the plasma processing chamber 10, and the substrate support 11 is formed inside the plasma processing chamber 10. The plasma processing chamber 10 is grounded. The shower head 16 and the substrate support 11 are electrically insulated from the plasma processing chamber 10.

The substrate support 11 includes a main body 12 and a ring assembly 13. The main body 12 has a central region 12a, which supports a substrate W, and an annular region 12b, which supports the ring assembly 13. A wafer is an example of the substrate W. The annular region 12b of the main body 12 surrounds the central region 12a of the main body 12 in a plan view. The substrate W is disposed on the central region 12a of the main body 12, and the ring assembly 13 is disposed on the annular region 12b of the main body 12 so as to surround the substrate W on the central region 12a of the main body 12. Therefore, the central region 12a is also called a substrate support surface that supports the substrate W, and the annular region 12b is also called a ring support surface that supports the ring assembly 13.

In one embodiment, the main body 12 includes a base 14 and an electrostatic chuck 15. The base 14 includes a conductive member. The conductive member of the base 14 may function as a lower electrode. The electrostatic chuck 15 is disposed on the base 14. The electrostatic chuck 15 includes a ceramic member 15a, and an electrostatic electrode 15b disposed in the ceramic member 15a. The ceramic member 15a has the central region 12a. In one embodiment, the ceramic member 15a also has the annular region 12b. Other members that surround the electrostatic chuck 15, such as an annular electrostatic chuck and an annular insulating member, may have the annular region 12b. In this case, the ring assembly 13 may be disposed on the annular electrostatic chuck or the annular insulating member, or may be disposed on both the electrostatic chuck 15 and the annular insulating member. At least one RF/DC electrode coupled to an RF power source 31 and/or a DC power source 32, which will be described later, may be disposed in the ceramic member 15a. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 14 and at least one RF/DC electrode may function as the lower electrodes. The electrostatic electrode 15b may function as the lower electrode. The substrate support 11 therefore includes at least one lower electrode.

The ring assembly 13 includes one or more annular members. In one embodiment, the one or more annular members include one or more edge rings and at least one cover ring. The edge ring is formed of a conductive material or an insulating material, and the cover ring is formed of an insulating material.

The substrate support 11 may include a temperature control module configured to adjust at least one of the ring assembly 13, the electrostatic chuck 15, and the substrate W to a target temperature. The temperature control module may include a heater, a heat transfer medium, a flow path 14a, or a combination thereof. A heat transfer fluid, such as a brine or gas, flows through the flow path 14a. In one embodiment, the flow path 14a is formed in the base 14, and one or more heaters are disposed in the ceramic member 15a of the electrostatic chuck 15. The substrate support 11 may include a heat transfer gas supply configured to supply a heat transfer gas to a gap between a rear surface of the substrate W and the central region 12a.

The shower head 16 is configured to introduce at least one processing gas from the gas supply 20 into the plasma processing space 10s. The shower head 16 has at least one gas supply port 16a, at least one gas diffusion chamber 16b, and a plurality of gas introduction ports 16c. The processing gas supplied to the gas supply port 16a passes through the gas diffusion chamber 16b and is introduced into the plasma processing space 10s from the gas introduction ports 16c. The shower head 16 includes at least one upper electrode. The gas introduction unit may include, in addition to the shower head 16, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 16 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses the flow rate of at least one processing gas.

The processing gas introduced from the gas supply 20 into the plasma processing space 10s includes a “first gas” and a “second gas”.

The first gas includes a processing gas for performing plasma processing on the substrate W loaded into the plasma processing chamber 10. In an example, the first gas includes an etching processing gas (e.g., a CₓH_{y}F_{z} gas, an O₂ gas, and an Ar gas) for etching an etching target layer formed on the substrate W.

The second gas includes a cleaning gas for performing a dry cleaning process (WLDC) in the plasma processing chamber 10. In an example, the second gas includes a cleaning gas (e.g., a CₓH_{y}F_{z} gas and a CO₂ gas) for removing organic deposits that are derived from the first gas and deposited in the chamber internal member of the plasma processing chamber 10.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Accordingly, the plasma is formed from at least one processing gas supplied into the plasma processing space 10s. Accordingly, the RF power source 31 may function as at least a part of the plasma generator 50. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode and configured to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### Inspection Apparatus

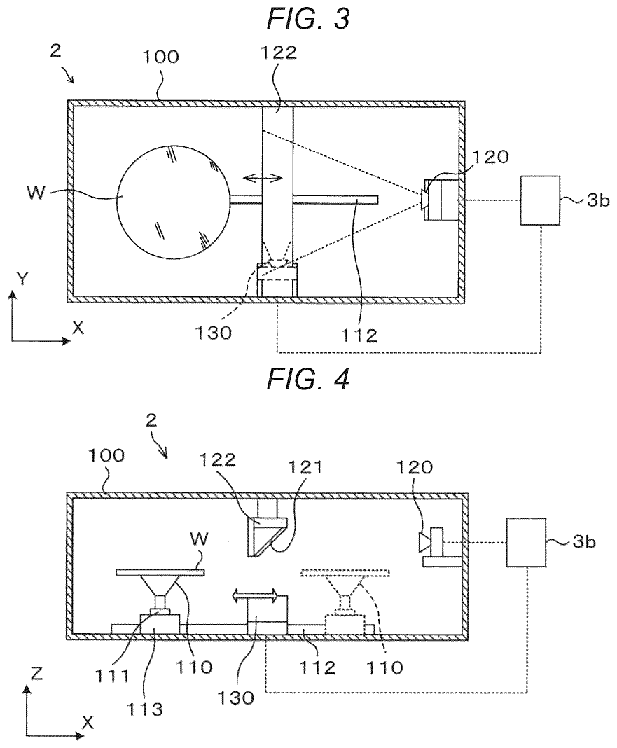

Next, an example of a configuration of an imaging apparatus that is an example of the inspection apparatus 2 will be described. FIG. 3 is a cross-sectional view illustrating a schematic configuration of the inspection apparatus 2. FIG. 4 is a vertical sectional view illustrating a schematic configuration of the inspection apparatus 2.

The inspection apparatus 2 has the casing 100 as shown in FIG. 3. The stage 110 on which the substrate W is placed is provided in the casing 100 as shown in FIG. 4. The stage 110 can be freely rotated and stopped by a rotation driving unit 111 such as a motor. A guide rail 112 extending from one end (an X-axis negative direction in FIG. 4) to the other end (an X-axis positive direction in FIG. 4) in the casing 100 is provided on a bottom surface of the casing 100. The stage 110 and the rotation driving unit 111 are provided on the guide rail 112, and can be moved along the guide rail 112 by a driving unit 113.

The surface imaging device 120 is provided on a side surface at the other end (the X-axis positive direction in FIG. 4) in the casing 100. As the surface imaging device 120, for example, a wide-angle CCD camera is used. A half mirror 121 is provided near an upper central portion of the casing 100. The half mirror 121 is provided at a position facing the surface imaging device 120 with a mirror surface tilted by 45 degrees upward toward the surface imaging device 120 from a state where the mirror surface faces vertically downward. A light source 122 is provided above the half mirror 121. The half mirror 121 and the light source 122 are fixed to an upper surface inside the casing 100. Illumination from the light source 122 passes through the half mirror 121 and is directed downward. Therefore, light reflected by an object located in an illuminated area is further reflected by the half mirror 121 and taken into the surface imaging device 120. That is, the surface imaging device 120 can image an object located in the illuminated area by the light source 122. The captured image is input to the inspection control device 3b.

In the inspection apparatus 2, when the substrate W moves along the guide rail 112 from the one end to the other end (from the X-axis negative direction to the X-axis positive direction in FIG. 4) within the casing 100, the surface imaging device 120 intermittently captures images to obtain an image of an entire surface of the substrate W. As a result, the inspection control device 3b acquires image data of the entire surface of the substrate W.

The end imaging device 130 is provided on one side surface (a Y-axis negative direction in FIG. 3) configuring a long side in the casing 100. As the end imaging device 130, for example, a wide-angle CCD camera is used. The end imaging device 130 receives light that is emitted downward from the light source 122 and passes through the half mirror 121, and is reflected toward the end imaging device 130 by an end of the object located in the illuminated area. That is, the surface imaging device 120 can capture an image of the end of the object located in an area illuminated by the light source 122. The captured image is input to the inspection control device 3b.

In the inspection apparatus 2, when the substrate W is directly below the light source 122 inside the casing 100, the stage 110 is rotated 360 degrees in a circumferential direction by the rotation driving unit 111, and during this time the end imaging device 130 intermittently captures an image of an outer end of the substrate W. As a result, the inspection control device 3b acquires image data of the entire outer end of the substrate W.

### Inspection Control Device 3b and Main Control Device 3a

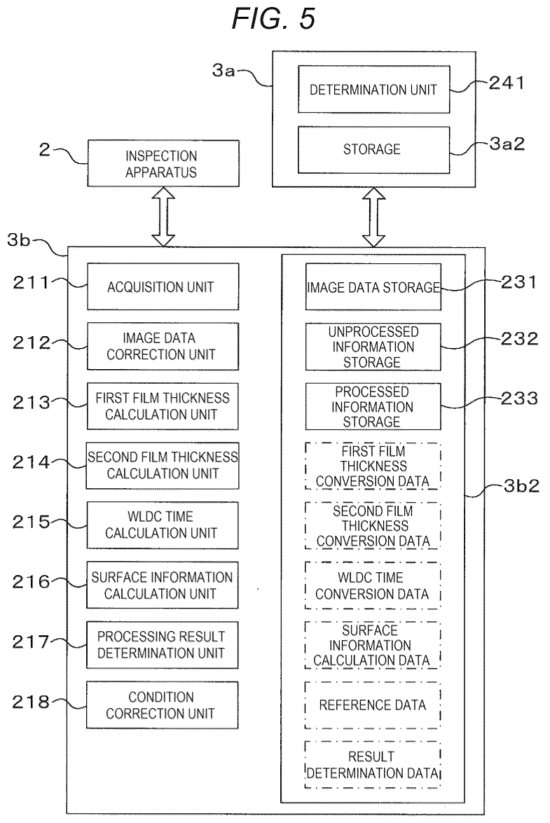

FIG. 5 is a functional block diagram of the inspection control device 3b and the main control device 3a related to inspection in the plasma processing system.

As shown in FIG. 5, the inspection control device 3b includes an acquisition unit 211, an image data correction unit 212, a first film thickness calculation unit 213, a second film thickness calculation unit 214, a WLDC time calculation unit 215, a surface information calculation unit 216, a processing result determination unit 217, and a condition correction unit 218, which are implemented when a processor such as a CPU reads and executes a program stored in the storage 3b2. The storage 3b2 of the inspection control device 3b includes an image data storage 231, an unprocessed information storage 232, and a processed information storage 233.

The main control device 3a includes a determination unit 241 implemented when a processor such as a CPU reads and executes a program stored in storage 3a2.

Based on an imaging result of the substrate W by the inspection apparatus 2, the acquisition unit 211 acquires image data of the substrate W, specifically, image data of the entire surface of the substrate W and image data of the entire outer end of the substrate W. The image data acquired by the inspection control device 3b is, for example, RGB data that represents luminance information for each of R (red), G (green), and B (blue) for each pixel. As the image data, data of a color system other than the RGB color system (for example, a CMYK color system) may be used. The image data acquired by the inspection control device 3b is stored in the image data storage 231.

The image data correction unit 212 corrects image data of the substrate W acquired by the acquisition unit 211 and used by the first film thickness calculation unit 213. Imaging results of the surface imaging device 120 may change due to, for example, changes over time in an intensity of light emitted from the light source 122 of the inspection apparatus 2 or a state of the light source 122 (e.g., a temperature of the light source 122). Therefore, the image data correction unit 212 corrects the image data of the substrate W acquired by the acquisition unit 211 based on, for example, a usage time of the light source 122 of the inspection apparatus 2 or the temperature of the light source 122. For this correction, for example, a conversion table is used for converting the usage time of the light source 122 or the temperature of the light source 122 into a correction amount of the image data (specifically, a correction amount of a pixel value). These conversion tables are calculated in advance and stored in the storage 3b2. For this correction, for example, the inspection control device 3b is provided with a timer (not illustrated) that measures a usage time of the light source 122, and the inspection apparatus 2 is provided with a temperature sensor (not illustrated) that measures a temperature of the surface imaging device 120.

The first film thickness calculation unit 213 calculates a thickness of a film on the substrate W based on the image data of the substrate W. Specifically, based on the image data of the substrate W, the first film thickness calculation unit 213 calculates a film thickness of deposits deposited on the substrate W after the plasma processing and a film thickness of the BSP adhering to a vicinity of an outer end of the rear surface of the substrate W after the plasma processing in the plasma processing apparatus 1. In the calculation by the first film thickness calculation unit 213, first film thickness conversion data for converting the luminance information on the image data of the substrate W into the thickness of the film is used. The first film thickness conversion data is acquired in advance and stored in the storage 3b2.

The first film thickness conversion data may be, for example, correlation between image data of a plurality of substrates W (or dummy substrates) and a deposition status of the deposits, which is obtained based on a result of plasma processing performed on the substrates W in advance in the plasma processing chamber 10.

The first film thickness calculation unit 213 may calculate information on deposits, the BSP, or the like deposited on the substrate W, for each region configuring the substrate W, based on image data of the region. That is, the first film thickness calculation unit 213 may acquire an in-plane distribution of deposition deposits or the BSP on the substrate W based on image data of the substrate W.

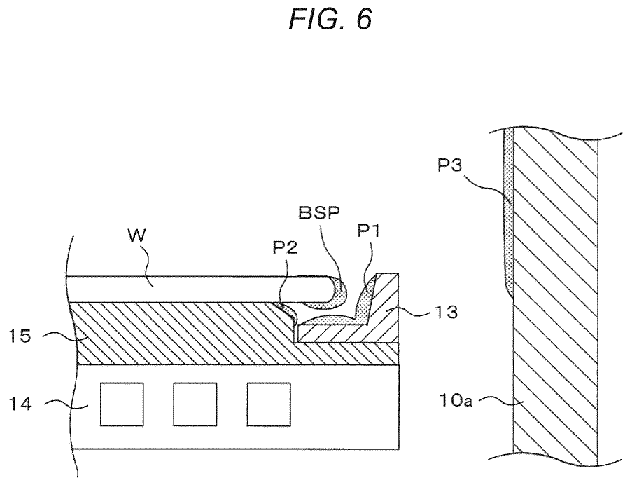

The second film thickness calculation unit 214 calculates a thickness of a film (polymer) deposited on the chamber internal member of the plasma processing chamber 10 by plasma processing in the plasma processing apparatus 1, based on film thickness information of the deposition deposits on the substrate W or film thickness information of the BSP calculated by the first film thickness calculation unit 213. Specifically, based on the film thickness information calculated by the first film thickness calculation unit 213, the second film thickness calculation unit 214 calculates a film thicknesses of a polymer P1 adhering to the ring assembly 13, a polymer P2 deposited on a shoulder of the electrostatic chuck 15, a polymer P3 adhering to the sidewall 10a of the plasma processing chamber 10, and the like after the plasma processing in the plasma processing apparatus 1, as illustrated in FIG. 6. In the calculation by the second film thickness calculation unit 214, second film thickness conversion data for converting the film thickness information of the deposits on the substrate W calculated by the first film thickness calculation unit 213 into the thicknesses of the polymers P1 to P3 is used. The second film thickness conversion data is acquired in advance and stored in the storage 3b2.

The second film thickness conversion data may be, for example, correlation between a deposition status of deposits on a plurality of substrates W (or dummy substrates) and a deposition status of polymers on chamber internal member, which is obtained based on a result of plasma processing performed on the substrates W in advance in the plasma processing chamber 10.

The polymer for which the film thickness calculation is performed by the second film thickness calculation unit 214 is not limited to the polymers P1 to P3 described above. In other words, the second film thickness calculation unit 214 may calculate a film thickness of a polymer deposited on any chamber internal member using any film thickness conversion data. As described above, the film thickness of the polymer P1 adhering to the ring assembly 13 and the polymer P2 adhering to the shoulder of the electrostatic chuck 15 become particularly large, particularly in a dry etching processing performed at an extremely low temperature. Therefore, in order to optimize and determine a time for the WLDC to be described later, the second film thickness calculation unit 214 according to the embodiment is preferably configured to calculate the film thickness of the polymer adhering to at least the ring assembly 13 or the shoulder of the electrostatic chuck 15 where the film thickness becomes large.

The WLDC time calculation unit 215 calculates a time for the WLDC to be described later in the plasma processing apparatus 1 based on the film thickness information of the polymer deposited on the chamber internal member calculated by the second film thickness calculation unit 214. Specifically, based on the largest film thickness among the film thickness information of the polymers P1 to P3 calculated by the second film thickness calculation unit 214, the WLDC time calculation unit 215 determines a WLDC time as a time for which a polymer having the largest film thickness can be appropriately removed. In the calculation by the WLDC time calculation unit 215, WLDC time conversion data for converting film thickness information of a polymer on the chamber internal member calculated by the second film thickness calculation unit 214 into a WLDC time is used. The WLDC time conversion data is acquired in advance and stored in the storage 3b2.

The WLDC time conversion data may be, for example, correlation between a WLDC time and an amount of the polymer removed, which is obtained based on results of the WLDC performed a plurality of times in advance in the plasma processing chamber 10.

The surface information calculation unit 216 calculates information on a surface state of the substrate W after the plasma processing in the plasma processing apparatus 1, based on the image data of the substrate W. The information on the surface state includes, for example, at least one of a film thickness of an etching target layer or a mask layer formed on the substrate W, pattern dimensions of the etching target layer or the mask layer formed on the substrate W, defect information on the substrate W, and appearance information of the substrate W. Information required for calculating or acquiring information on a surface state is acquired in advance as surface information calculation data and stored in the storage 3b2.

The processing result determination unit 217 determines a result of the plasma processing performed based on the information about the etched substrate W calculated by the surface information calculation unit 216. The processing result determination unit 217 determines the result of the plasma processing, i.e., a level of performance, based on, for example, at least one of the pieces of the surface information about the substrate W after the plasma processing calculated by the surface information calculation unit 216.

In the determination of the result of the plasma processing by the processing result determination unit 217, information about the substrate W before the plasma processing calculated by the surface information calculation unit 216 may also be used. Specifically, for example, the processing result determination unit 217 may determine a level of a result of the plasma processing based on a difference between information about the substrate W before the plasma processing and information about the substrate W after the plasma processing.

Data required for the processing result determination unit 217 to determine the result of plasma processing based on information about the substrate W after the plasma processing is acquired in advance as result determination data and stored in the storage 3b2.

The condition correction unit 218 corrects conditions for plasma processing performed on the substrate W based on the surface information of the substrate W calculated by the surface information calculation unit 216. Specifically, for example, the condition correction unit 218 compares the surface state of one substrate W after the plasma processing calculated by the surface information calculation unit 216 with a surface state (reference data) of a reference wafer after the plasma processing stored in advance in the storage 3b2 as a threshold value, and calculates a difference value, thereby calculating a correction amount for a plasma processing condition for another substrate W to be subjected to the plasma processing later so that the difference value becomes small (so as to approach the surface state of the target reference wafer).

The plasma processing system corrects the processing conditions of the plasma etching processing based on the correction amount calculated by the condition correction unit 218, and performs plasma processing on the corresponding substrate W under corrected processing conditions.

That is, the condition correction unit 218 is for feeding forward the surface information about one substrate W after plasma processing calculated by the surface information calculation unit 216 to plasma processing conditions for another substrate W by the plasma processing system.

Instead of feeding forward the surface state of one substrate W after the plasma processing to the plasma processing condition for the other substrate W, the condition correction unit 218 may be used to feed forward the surface state of one substrate W to the plasma processing condition for the same substrate W. That is, after the surface information calculation unit 216 calculates a surface state of one substrate W before plasma processing, the surface state of one substrate W before the plasma processing may be fed forward to a plasma processing condition for the same substrate W.

The main control device 3a acquires in advance a processing recipe for the substrate W as a processing target when performing wafer processing including inspection of the substrate W, or acquires the processing recipe when starting the processing, and stores the processing recipe in storage 3a2. The processing recipes include a plasma processing recipe and an inspection recipe.

### Wafer Processing

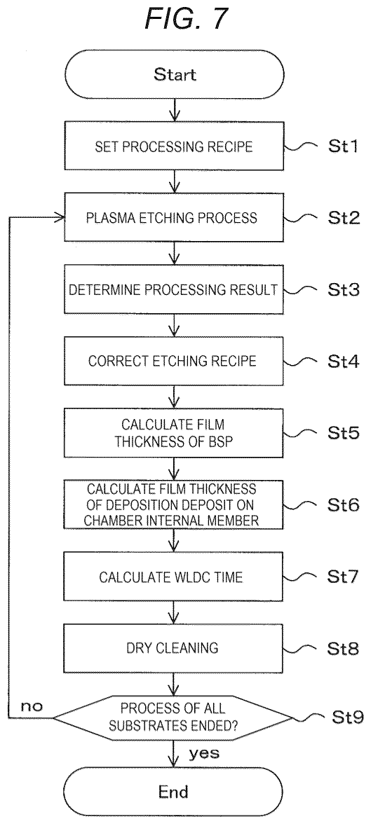

The plasma processing system according to the embodiment is configured as described above. Next, wafer processing, including the WLDC in the plasma processing chamber 10, performed using this plasma processing system will be described. FIG. 7 is a flowchart illustrating the main steps of the plasma processing according to the present embodiment.

In the following description, in the plasma processing apparatus 1, a plasma etching processing is performed on the substrate W in which an etching target layer is stacked on a surface, using a mask layer on which a pattern is formed as a mask.

### Step St1

First, a series of processing recipes in the plasma processing system is set. The set processing recipes include, for example, etching processing conditions for the substrate W in the plasma processing apparatus 1, inspection conditions for the substrate W in the inspection apparatus 2, and a WLDC time in the plasma processing apparatus 1.

### Step St2

In step St2, an etching processing is performed on the substrate W as a processing target under plasma processing conditions set in step St1. The etching processing for the substrate W is performed under control of, for example, the main control device 3a.

Specifically, first, the substrate W as the processing target, which has an etching target layer (not illustrated) and a mask layer (not illustrated) formed on a surface thereof, is loaded into the plasma processing chamber 10 by a substrate transfer robot (not illustrated) provided outside the plasma processing apparatus 1. The loaded substrate W is placed on the substrate support 11, and then attracted and held by the electrostatic chuck 15 by supplying a direct-current voltage to the electrostatic chuck 15. When the substrate W is held on the electrostatic chuck 15, an inside of the plasma processing chamber 10 is depressurized to a desired vacuum level by the exhaust system 40.

Next, the first gas is supplied from the gas supply 20 to the plasma processing space 10s through the shower head 16. The first RF generator 31a supplies source RF power to the lower electrode to excite an etching gas in the first gas to generate plasma. Further, the second RF generator 31b supplies bias RF power to the lower electrode to draw an ion component in the formed plasma toward the substrate W. Accordingly, the etching target layer formed on the substrate W is subjected to an etching processing by an action of the generated plasma.

When a desired etching result is obtained for the etching target layer, the etching processing in the plasma processing apparatus 1 is ended. When the etching processing is ended, first, the supply of the source RF power and the bias RF power from the RF power source 31, the application of the direct-current voltage from the DC power source 32, and the supply of the first gas from the gas supply 20 are stopped. Next, the electrostatic chuck 15 stops attracting and holding the substrate W. At this time, the first gas remaining in the plasma processing chamber 10 is exhausted to an outside by the exhaust system 40.

The substrate W subjected to the etching processing is then unloaded from the plasma processing chamber 10 by a substrate transfer robot (not illustrated) and the etching processing on the substrate W in the plasma processing apparatus 1 is ended.

In step St2, the etching processing is performed on the substrate W under the plasma processing conditions set in advance in step St1. However, for example, the substrate W as the processing target may be transferred to the inspection apparatus 2 before being transferred to the plasma processing apparatus 1, and the etching target layer and the mask layer formed on the surface of the substrate W may be imaged and inspected. In this case, the surface information calculation unit 216 may calculate surface information (e.g., at least one of a pattern dimension of the mask layer, defect information of the substrate W, a thickness of a film on the substrate W, and appearance information of the substrate W) based on image data of the substrate W before the etching process, and the condition correction unit 218 may correct the plasma processing condition in step St2 based on this calculation.

### Step St3

In step St3, a surface state of the substrate W subjected to the etching processing in step St2 is inspected, and a processing result of the etching processing is determined. The inspection of the surface state of the substrate W is performed under control of, for example, the inspection control device 3b.

Specifically, first, the substrate W as the processing target after the etching processing is loaded into the casing 100 by a substrate transfer robot (not illustrated) provided outside the inspection apparatus 2. The loaded substrate W is placed on the stage 110. At this time, the substrate W is placed on the stage 110 such that the surface as a processing target surface, on which the etching target layer is formed, faces upward.

Next, the stage 110 holding the substrate W is moved along a horizontal direction, so that the surface of the substrate W is imaged by the surface imaging device 120 so as to be scanned.

Next, the acquisition unit 211 of the inspection control device 3b acquires image data of the substrate W based on the imaging results of the substrate W after the etching processing by the surface imaging device 120, and stores the image data in the image data storage 231. The image data acquired and stored here is, for example, RGB data.

The image data of the substrate W after the etching processing obtained by the surface imaging device 120 may be corrected by the image data correction unit 212.

Subsequently, the surface information calculation unit 216 calculates surface information (e.g., at least one of a pattern dimension of a mask layer, defect information of the substrate W, a thickness of a film on the substrate W, and appearance information of the substrate W) of the substrate W after the etching processing based on the acquired image data.

Next, the processing result determination unit 217 determines a result of the etching processing based on the surface information of the substrate W calculated by the surface information calculation unit 216.

Specifically, the processing result determination unit 217 determines an etching processing result, i.e., a level of performance, based on at least one of the pieces of the surface information calculated by the surface information calculation unit 216. For this determination, the surface information of the substrate W after the etching processing calculated by the surface information calculation unit 216 and the result determination data acquired in advance may be used.

A determination result of the etching processing by the processing result determination unit 217 is output, for example, to a quality control server external to the plasma processing system.

When the surface information calculated by the surface information calculation unit 216 indicates an abnormal value (for example, when the number of defects exceeds a threshold value or when appearance data matches abnormal data), an operation of the plasma processing system may be stopped, and plasma processing on the subsequent substrate W may be stopped.

### Step St4

In step St4, based on the surface information calculated by the surface information calculation unit 216, the condition correction unit 218 calculates a correction amount for a condition for an etching processing for the subsequent substrate W, and outputs the correction amount to the main control device 3a.

For this calculation, a difference between the surface information calculated by the surface information calculation unit 216 and surface information of a reference wafer after the etching processing acquired in advance may be used.

### Step St5

In step St5, a film thickness of deposits deposited on the substrate W subjected to the etching processing in step St2 is calculated. The calculation of the film thickness of the deposits on the substrate W is performed under control of the inspection control device 3b, for example.

As described above, during the etching processing in the plasma processing apparatus 1, organic deposits, which are reaction products, adhere to and are deposited on the substrate W as the processing target or the chamber internal member of the plasma processing chamber 10 (see, e.g., FIG. 6). Deposits adhering to the substrate W or the chamber internal member may cause, for example, a malfunction of the apparatus or a malfunction of a processing result for the substrate W.

Therefore, in the plasma processing system according to the present embodiment, after the etching processing for the substrate W described above is ended, a plasma cleaning process (WLDC) for removing the deposits adhering to the chamber internal member is performed in the same plasma processing chamber 10.

In the present embodiment, a processing time of the WLDC for removing the deposits adhering to the chamber internal member is determined based on a film thickness of BSP adhering to a vicinity of the outer end of the rear surface of the substrate W after the plasma processing. That is, measurement of the film thickness of the BSP in step St5 is performed to determine the processing time of the WLDC.

Specifically, first, the substrate W for which the surface state is inspected in step St3 is turned upside down by an inversion device (not illustrated), and then loaded into the casing 100 by a substrate transfer robot (not illustrated). The loaded substrate W is placed on the stage 110. At this time, the substrate W is placed on the stage 110 such that the rear surface that is an inspection target surface to which the BSP adheres faces upward.

Next, the stage 110 holding the substrate W is moved along the horizontal direction, so that the rear surface of the substrate W is imaged by the surface imaging device 120 so as to be scanned.

The stage 110 holding the substrate W is rotated 360 degrees in the circumferential direction directly below the light source 122 in the casing 100, so that an image is captured by the end imaging device 130 around the entire outer end of the substrate W.

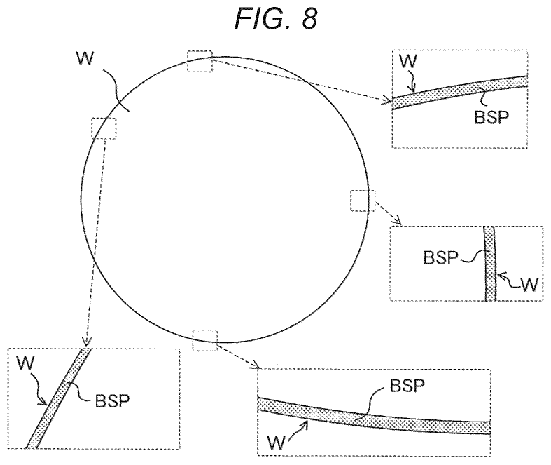

Next, the acquisition unit 211 of the inspection control device 3b acquires image data of the substrate W (see FIG. 8) based on imaging results of the substrate W after the etching processing by the surface imaging device 120 and the end imaging device 130, and stores the image data in the image data storage 231. The image data acquired and stored here is, for example, RGB data.

The image data of the substrate W after the etching processing obtained by the surface imaging device 120 and the end imaging device 130 may be corrected by the image data correction unit 212.

Subsequently, the first film thickness calculation unit 213 calculates the film thickness of the BSP (see, e.g., FIG. 6) adhering to the vicinity of the outer end of the rear surface of the substrate W, based on the image data of the substrate W after the etching process.

Specifically, the first film thickness calculation unit 213 calculates the film thickness of the BSP based on the image data of the substrate W after the etching processing obtained by the surface imaging device 120 and the end imaging device 130 and the first film thickness conversion data acquired in advance.

More specifically, the RGB data, which is image data of the substrate W, is converted into film thickness data of the BSP using the first film thickness conversion data.

Step St6 In step St6, a film thickness of the deposits (the polymers P1 to P3 in FIG. 6) deposited on the chamber internal member of the plasma processing chamber 10 after the etching processing is calculated based on the film thickness data of the BSP calculated in step St5. The calculation of the film thicknesses of the polymers P1 to P3 is performed under control of the inspection control device 3b, for example.

Specifically, the second film thickness calculation unit 214 calculates the film thicknesses of the polymers P1 to P3 based on the film thickness data of the BSP calculated in step St5 and the second film thickness conversion data acquired in advance.

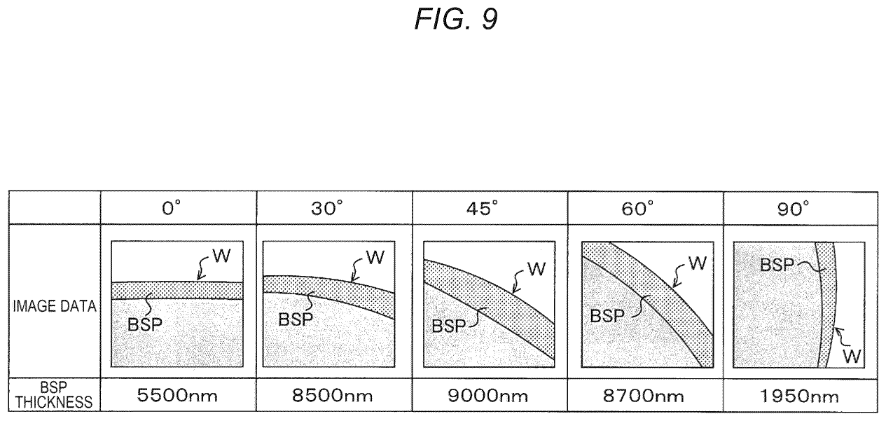

As shown in FIG. 9, the BSP adhering to the substrate W by the etching processing varies depending on a circumferential position of the substrate W. Specifically, it can be seen that the BSP adhering to the substrate W tends to be thickest at positions of 0 degrees to 60 degrees with respect to a notch (not illustrated) formed in the substrate W.

Therefore, in step St6, among BSPs with different amounts of adhesion at circumferential positions, it is preferable to calculate the film thickness of the polymer deposited on the chamber internal member based on a radial position where an amount of adhesion of the BSP is the largest (a position at 45 degrees in an example in FIG. 9).

Accordingly, since the film thicknesses of the polymers P1 to P3 are estimated based on the portion where the amount of adhesion of the BSP is the largest, it is possible to prevent the polymer from remaining in the chamber internal member after the WLDC to be described later.

### Step St7

In step St7, the WLDC time of the plasma processing chamber 10 is calculated based on the film thickness data of the polymer calculated in step St6. The calculation of the WLDC time is performed under control of the inspection control device 3b, for example.

Specifically, the WLDC time calculation unit 215 calculates a time for the WLDC based on the film thickness data of the polymer calculated in step St6 and the WLDC time conversion data acquired in advance.

More specifically, the WLDC time set in advance in step St1 is corrected so as to obtain a time for properly removing a polymer having the largest film thickness among film thickness data of a plurality of polymers calculated in step St6 (in the present embodiment, the three pieces of film thickness data corresponding to the polymer P1 adhering to the ring assembly 13, the polymer P2 deposited on the shoulder of the electrostatic chuck 15, and the polymer P3 adhering to the sidewall 10a of the plasma processing chamber 10).

That is, when the WLDC time set in step St1 is short with respect to the film thickness of the polymer calculated in step St6, arcing may occur due to the polymer remaining in the plasma processing chamber 10, and thus the WLDC time is lengthened.

When the WLDC time set in step St1 is long with respect to the film thickness of the polymer calculated in step St6, there is a concern that this WLDC may cause a decrease in throughput in the plasma processing system, so the WLDC time is shortened.

### Step St8

In step St8, the WLDC of the plasma processing chamber 10 is performed for the WLDC time calculated in step St7. As the name suggests, the WLDC of the plasma processing chamber 10 is performed in a state where the substrate W is unloaded from the plasma processing chamber 10, i.e., in a state where the substrate W is not provided in the plasma processing chamber 10. The WLDC of the plasma processing chamber 10 is performed under control of the main control device 3a, for example.

Specifically, first, the second gas is supplied from the gas supply 20 to the plasma processing space 10s through the shower head 16. The first RF generator 31a supplies source RF power to the lower electrode to excite an etching gas in the first gas to generate plasma. Accordingly, the polymer deposited on the chamber internal member is removed by an action of the generated plasma.

When a processing time set in step St7 elapses after start of the WLDC, the WLDC in the plasma processing apparatus 1 is ended. When the WLDC is ended, supply of the source RF power from the RF power source 31 and supply of the second gas by the gas supply 20 are stopped. At this time, the second gas remaining in the plasma processing chamber 10 is exhausted to the outside by the exhaust system 40. Accordingly, removal of the polymer (WLDC) in the plasma processing apparatus 1 is ended.

### Step St9

In step St9, it is determined whether the etching processing is performed on all of the substrates W loaded into the plasma processing system, for example, all of the substrates W in one lot accommodated in a FOUP (not illustrated).

If it is determined in step St9 that an unprocessed substrate W remains, an etching processing (step St2) with respect to the next substrate W (another substrate W) in the plasma processing apparatus 1 is started.

At this time, a condition for the etching processing for the next substrate W is set based on a new etching processing condition corrected based on the processing result (the surface information calculated in step St4) of the substrate W (one substrate W) processed immediately before in step St5 described above.

Accordingly, it is possible to appropriately improve a result of the etching processing performed on the next substrate W.

The processing time of the WLDC (step St8) performed in the plasma processing apparatus 1 after the etching processing performed on the next substrate W is corrected again based on a processing result of the next substrate W (the film thickness of BSP deposited on the next substrate W calculated in step St5) (step St7).

Accordingly, by correcting the condition of the etching processing described above, even when a deposition amount of the polymer due to the plasma processing on the next substrate W changes from a deposition amount of the polymer during the plasma processing on the previous substrate W, the processing time of the WLDC can be optimized and the polymer deposited on the chamber internal member can be appropriately removed.

Thereafter, if it is determined in step St9 that no unprocessed substrate W remains, a series of wafer process in the plasma processing system is ended.

### Operations and Effects of Technique of Present Disclosure

As described above, according to the plasma processing method in the present embodiment, the film thickness of the BSP is calculated based on the image data of the substrate W after the etching processing acquired based on the imaging result of the inspection apparatus 2 of the plasma processing system, and further, the WLDC time of the plasma processing chamber 10 is determined based on the film thickness of the BSP. That is, in the plasma processing according to the present embodiment, the film thickness of the deposition deposit on the chamber internal member, which is difficult to measure directly in the related art, is indirectly calculated via the film thickness of the BSP, which is easy to measure, and the WLDC time is determined. Accordingly, the WLDC time of the plasma processing chamber 10 may be optimized, and occurrence of arcing may be prevented while improving throughput related to the WLDC.

In the present embodiment, the WLDC time is calculated based on a portion of BSP having the largest film thickness of the BSP among film thicknesses of the BSP at 360 degrees in the circumferential direction of the substrate W calculated by the first film thickness calculation unit 213. Further, similarly, the WLDC time is calculated based on data having the largest film thickness of a polymer among the film thickness data of a plurality of polymers calculated by the second film thickness calculation unit 214. Accordingly, it is possible to prevent a polymer from remaining in the plasma processing chamber 10 in the subsequent WLDC, and to further appropriately prevent occurrence of arcing.

Further, in the present embodiment, the film thickness of the BSP is measured for each of the substrates W subjected to the etching processing in the plasma processing apparatus 1, and the WLDC time is corrected for each of the substrates W. Accordingly, even if conditions of the etching processing for the substrates W are corrected for each substrate, and a deposition amount of the polymer on the chamber internal member changes for each substrate, the WLDC can be appropriately set in accordance therewith.

In the present embodiment, the film thickness of the BSP deposited on the substrate W is calculated using an imaging mechanism (inspection apparatus 2) that is used for performance inspection after plasma processing in the related art, and the WLDC time can be set. Therefore, it is not necessary to introduce a new facility into the plasma processing system to optimize the WLDC time. Since it is possible to calculate the film thickness of the BSP and correct the WLDC time simply by capturing an image of the substrate W after the etching process, control is easy as well.

In the embodiment, the WLDC time is set by using at least one of the polymers P1 to P3 deposited on the ring assembly 13, the electrostatic chuck 15, or the sidewall 10a serving as the chamber internal member. However, when it is suggested that a deposition amount of a polymer becomes large in another chamber internal member due to, for example, the etching processing condition, the deposition amount of the polymer on the other chamber internal member may be calculated, and the WLDC time may be set. In this case, the storage 3b2 preferably stores other film thickness conversion data for converting the film thickness information of the deposit on the substrate W calculated by the first film thickness calculation unit 213 into a film thickness of a polymer deposited on the other chamber internal member.

The other film thickness conversion data may be, for example, correlation between a deposition status of deposits on a plurality of substrates W (or dummy substrates) and a deposition status of polymers on the other chamber internal member, which is obtained based on a result of plasma processing performed in advance on the substrates W in the plasma processing chamber 10.

In the embodiment, the inspection apparatus 2 measures a film thickness of reaction products deposited on the substrate W by imaging the substrate W after the plasma processing. However, a configuration of the inspection apparatus 2 is not limited thereto. That is, as long as the film thickness of the reaction products deposited on the substrate W after the plasma processing can be measured and calculated, measurement using, for example, a displacement meter or other methods may be used instead of imaging the substrate W.

In the embodiment, an example is described in which the plasma etching processing is performed on the substrate W in the plasma processing apparatus 1, but the process performed in the plasma processing apparatus 1 is not limited to the etching process. That is, the technique according to the present disclosure can be applied as long as any process performed on the substrate W in the plasma processing apparatus 1 is performed and there is a concern that a polymer may adhere to the chamber internal member.

In the embodiment, an example is described in which a time for dry cleaning is set based on the thickness of the reaction products as an example, but the plasma processing method is not limited to this example. That is, the technique according to the present disclosure can be applied as long as a plasma generation condition in the plasma cleaning process (WLDC) is set, such as radio frequency (RF) power, a frequency of a radio frequency (RF), a type of a cleaning gas, and a pressure in a chamber.

It shall be understood that the embodiments disclosed herein are illustrative and are not restrictive in all aspects. The embodiment described above may be omitted, replaced, or modified in various forms without departing from the scope and spirit of the appended claims. For example, the constituent elements of the embodiment may be combined as desired as long as effects of each are not impaired.

The following configuration examples also fall within the technical scope of the present disclosure.

(1) A plasma processing method includes:
a step A performing plasma processing on a substrate introduced into a processing chamber,
a step B calculating a thickness of a reaction product deposited on the substrate by the step A,
a step C setting a time for dry cleaning to remove a reaction product deposited inside the processing chamber by the step Abased on the thickness of the reaction product calculated in the step B, and
a step D performing the dry cleaning for the time set in the step C in a state where the substrate is unloaded from the processing chamber.

(2) The plasma processing method according to (1), in which
the step B includes
   a step B1 acquiring image data of the substrate after the plasma processing, and
   a step B2 converting the image data into thickness data of the reaction product.

(3) The plasma processing method according to (1) or (2), in which
the thickness of the reaction product calculated in the step B is a thickness of a backside polymer (BSP) deposited on an outer end of a rear surface of the substrate.

(4) The plasma processing method according to (3), in which
in the step C, the time for the dry cleaning is set based on a portion having a largest thickness of the BSP among thicknesses of the BSP calculated in an entire circumference of the substrate in a circumferential direction.

(5) The plasma processing method according to any one of (1) to (4), in which
the step C includes
   a step C1 calculating a thickness of the reaction product deposited inside the processing chamber based on the thickness of the reaction product on the substrate calculated in the step B, and
   a step C2 setting the time for the dry cleaning based on the thickness of the reaction product calculated in the step C1.

(6) The plasma processing method according to (5), in which
in the step C1, thicknesses of the reaction product at a plurality of locations in the processing chamber are calculated, and
in the step C2, the time for dry cleaning is set based on a location where a thickness of the reaction product is the largest among the thicknesses of the reaction product at the plurality of locations.

(7) The plasma processing method according to (5) or (6), in which
in the step C1, a thickness of a reaction product deposited on a chamber internal member disposed in the processing chamber is calculated, and
the chamber internal member is at least any one of a ring assembly disposed around the substrate in the step A, a shoulder of an electrostatic chuck that attracts and holds the substrate, and an inner wall of the processing chamber.

(8) The plasma processing method according to any one of (1) to (7), in which
the plasma processing is an etching processing for forming a pattern in an etching target layer formed on a surface of the substrate.

(9) A plasma processing system including:
an inspection apparatus including an imaging mechanism configured to image a substrate,
a plasma processing apparatus configured to perform plasma processing on the substrate inside a processing chamber, and
a controller configured to calculate a thickness of a reaction product deposited on the substrate after the plasma processing based on image data of the substrate after the plasma processing imaged by the inspection apparatus, and set a time for dry cleaning to remove a reaction product deposited inside the processing chamber after the plasma processing based on the calculated thickness of the reaction product.

(10) The plasma processing system according to (9), in which
the controller converts the image data of the substrate after the plasma processing imaged by the inspection apparatus into the thickness of the reaction product deposited on the substrate.

(11) The plasma processing system according to (9) or (10), in which
the controller acquires a calculated thickness of a backside polymer (BSP) deposited on an outer end of a rear surface of the substrate as the thickness of the reaction product.

(12) The plasma processing system according to any one of (9) to (11), in which
the controller calculates a thickness of the reaction product deposited inside the processing chamber based on the calculated thickness of the reaction product on the substrate, and sets the time for the dry cleaning based on the calculated thickness of the reaction product.

(13) The plasma processing system according to any one of (9) to (12), in which
the controller acquires a thickness of a reaction product deposited on a chamber internal member disposed in the processing chamber as the thickness of the reaction product deposited inside the processing chamber, and
the chamber internal member is at least any one of a ring assembly disposed around the substrate during the plasma processing, a shoulder of an electrostatic chuck that attracts and holds the substrate, and an inner wall of the processing chamber.

1. A plasma processing method comprising:
(A) performing plasma processing on a substrate introduced into a processing chamber,
(B) calculating a thickness of a reaction product deposited on the substrate by (A),
(C) setting a time for dry cleaning to remove a reaction product deposited inside the processing chamber by (A) based on the thickness of the reaction product deposited on the substrate calculated in (B), and
(D) performing the dry cleaning for the time set in (C) in a state where the substrate is unloaded from the processing chamber.

2. The plasma processing method according to claim 1, wherein (B) includes:
(B1) acquiring image data of the substrate after the plasma processing, and
(B2) converting the image data into thickness data of the reaction product deposited on the substrate.

3. The plasma processing method according to claim 1, wherein the thickness of the reaction product deposited on the substrate calculated in (B) is a thickness of a backside polymer deposited on an outer end of a rear surface of the substrate.

4. The plasma processing method according to claim 3, wherein, in (C), the time for the dry cleaning is set based on a portion of the backside polymer having a largest thickness among thicknesses of the backside polymer calculated in an entire circumference of the substrate in a circumferential direction.

5. The plasma processing method according to claim 1, wherein (C) includes:
(C1) calculating a thickness of the reaction product deposited inside the processing chamber based on the thickness of the reaction product deposited on the substrate calculated in (B), and
(C2) setting the time for the dry cleaning based on the thickness of the reaction product deposited inside the processing chamber calculated in (C1).

6. The plasma processing method according to claim 5, wherein
in (C1), thicknesses of the reaction product deposited at a plurality of locations in the processing chamber are calculated, and
in (C2), the time for the dry cleaning is set based on a location where a thickness of the reaction product deposited inside the processing chamber is the largest among the thicknesses of the reaction product deposited at the plurality of locations.

7. The plasma processing method according to claim 5, wherein
in (C1), a thickness of a reaction product deposited on a chamber internal member disposed in the processing chamber is calculated, and
the chamber internal member is at least any one of a ring assembly disposed around the substrate in (A), an electrostatic chuck that attracts and holds the substrate, and an inner wall of the processing chamber.

8. The plasma processing method according to claim 1, wherein
(B) includes:
(B1) acquiring image data of the substrate after the plasma processing, and
(B2) converting the image data into thickness data of the reaction product deposited on the substrate, and
(C) includes:
(C1) calculating a thickness of the reaction product deposited inside the processing chamber based on the thickness of the reaction product deposited on the substrate calculated in (B), and
(C2) setting the time for the dry cleaning based on the thickness of the reaction product deposited inside the processing chamber calculated in (C1).

9. The plasma processing method according to claim 8, wherein the thickness of the reaction product deposited on the substrate calculated in (B) is a thickness of a backside polymer deposited on an outer end of a rear surface of the substrate.

10. The plasma processing method according to claim 9, wherein, in (C), the time for the dry cleaning is set based on a portion of the backside polymer having a largest thickness among thicknesses of the backside polymer calculated in an entire circumference of the substrate in a circumferential direction.

11. The plasma processing method according to claim 8, wherein
in (C1), thicknesses of the reaction product deposited at a plurality of locations in the processing chamber are calculated, and
in (C2), the time for the dry cleaning is set based on a location where a thickness of the reaction product deposited inside the processing chamber is the largest among the thicknesses of the reaction product deposited at the plurality of locations.

12. The plasma processing method according to claim 11, wherein
in (C1), a thickness of a reaction product deposited on a chamber internal member disposed in the processing chamber is calculated, and
the chamber internal member is at least any one of a ring assembly disposed around the substrate in (A), an electrostatic chuck that attracts and holds the substrate, and an inner wall of the processing chamber.

13. The plasma processing method according to claim 1, wherein the plasma processing is an etching processing for forming a pattern in an etching target layer formed on a surface of the substrate.

14. A plasma processing system comprising:
an inspection apparatus including an imaging mechanism configured to image a substrate,
a plasma processing apparatus configured to perform plasma processing on the substrate inside a processing chamber, and
processing circuitry configured to:
calculate a thickness of a reaction product deposited on the substrate after the plasma processing based on image data of the substrate after the plasma processing imaged by the inspection apparatus, and
set a time for dry cleaning to remove a reaction product deposited inside the processing chamber after the plasma processing based on the calculated thickness of the reaction product deposited on the substrate.

15. The plasma processing system according to claim 14, wherein the processing circuitry is configured to convert the image data of the substrate after the plasma processing imaged by the inspection apparatus into the thickness of the reaction product deposited on the substrate.

16. The plasma processing system according to claim 15, wherein the processing circuitry is configured to acquire a calculated thickness of a backside polymer deposited on an outer end of a rear surface of the substrate as the thickness of the reaction product deposited on the substrate.

17. The plasma processing system according to claim 14, wherein the processing circuitry is configured to:
calculate a thickness of the reaction product deposited inside the processing chamber based on the calculated thickness of the reaction product deposited on the substrate, and
set the time for the dry cleaning based on the calculated thickness of the reaction product deposited inside the processing chamber.

18. The plasma processing system according to claim 17, wherein
the processing circuitry is configured to acquire a thickness of a reaction product deposited on a chamber internal member disposed in the processing chamber as the thickness of the reaction product deposited inside the processing chamber, and
the chamber internal member is at least any one of a ring assembly disposed around the substrate during the plasma processing, a shoulder of an electrostatic chuck that attracts and holds the substrate, and an inner wall of the processing chamber.
